(19) United States
(12) Patent Application Publication
(10) Pub. No.: US 2026/0354232 A1
(43) Pub. Date: Nov. 5, 2026

(54) Package with Flip-Chip Electronic Component on Inorganic Carrier and Lateral Thickening Structure

(71) Applicant: Infineon Technologies Austria AG, Villach (AT)

(72) Inventors: Andreas Grassmann, Sinzing (DE); Ivan Nikitin, Regensburg (DE)

(21) Appl. No.: 19/662,304

(22) Filed: Apr. 29, 2026

(30) Foreign Application Priority Data
Apr. 30, 2025 (DE) 102025116690.0

(51) Int. Cl. H10W 70/652; H10W 70/00; H10W 70/40; H10W 70/655; H10W 74/10; H10W 90/00

(52) U.S. Cl. CPC H10W 70/6528; H10W 70/099; H10W 70/479; H10W 70/655; H10W 74/114; H10W 90/754; H10W 90/794

(57) ABSTRACT

A package includes: an inorganic carrier having a main surface at which an electrically conductive pattern is formed; an electronic component having electrically conductive pads and being mounted in a flip-chip configuration on the carrier so that the pads are electrically coupled with the electrically conductive pattern; and an electrically conductive lateral thickening structure arranged laterally from the electronic component and being electrically coupled with at least part of the pads. A thickness of the lateral thickening structure is larger than a thickness of the electrically conductive pattern.

### TECHNICAL FIELD

The present invention relates to a package and to a method of manufacturing a package.

### BACKGROUND

A package, for instance for automotive applications, provides a physical containment for one or more electronic chips comprising one or more integrated circuit elements. Examples of integrated circuit elements of packages are a metal oxide semiconductor field effect transistor (MOSFET), an insulated-gate bipolar transistor (IGBT), and a diode.

There is still potentially room to enable package manufacture with short electric paths, low loss and high thermal performance.

### SUMMARY

There may be a need for a package with better electric paths and better thermal performance, in particular when one or more chips inside the package become smaller and smaller.

According to an exemplary embodiment, a package is provided which comprises an inorganic carrier having a main surface at which an electrically conductive pattern is formed, an electronic component having electrically conductive pads and being mounted in a flip-chip configuration on the carrier so that the pads are electrically coupled with the pattern, and an electrically conductive lateral thickening structure arranged laterally from the electronic component and being electrically coupled with at least part of the pads, wherein a thickness of the lateral thickening structure is larger than a thickness of the pattern.

According to another exemplary embodiment, a method of manufacturing a package is provided, wherein the method comprises providing an inorganic carrier having a main surface at which an electrically conductive pattern is formed, mounting an electronic component in a flip-chip configuration on the carrier so that electrically conductive pads of the electronic component are electrically coupled with the pattern, and arranging an electrically conductive lateral thickening structure laterally from the electronic component and being electrically coupled with at least part of the pads, wherein a thickness of the lateral thickening structure is larger than a thickness of the pattern.

According to an exemplary embodiment, a package (which may be a semiconductor power package) may be formed based on an inorganic carrier, such as a metal-coated ceramic plate. An electrically conductive pattern, like a structured metal layer on a ceramic plate, may form a mechanical and electric basis for one or more electronic components to be mounted thereon. Such one or more electronic components may have electrically conductive pads, like chip terminals (for instance source, drain and gate terminals in case of a field-effect transistor chip). Said at least one electronic component may be arranged in flip-chip configuration on the carrier, i.e. may be mounted upside down or with pads face-down. By electrically coupling the pads of the at least one electronic component with the patterned electrically conductive structure on a top side of the inorganic carrier, short electric paths may be achieved. Moreover, an electrically conductive lateral thickening structure may be located sideways or laterally from the electronic component, preferably extending vertically along at least part of sidewalls of the electronic component. By electrically coupling said electrically conductive lateral thickening structure with one or more pads of the at least one electronic component via the pattern, a low ohmic electric connection may be obtained. This may be achievable in particular by the combination of the metallic pattern and the lateral thickening structure. Since inorganic, preferably ceramic, carrier materials may show good thermal conductivity and preferably metallic material of the lateral thickening structure may also have a high thermal conductivity, low electric losses may be combined with an excellent thermal performance. The assembly of a flip-chip mounted electronic component on an inorganic, preferably ceramic, carrier has advantages: On the one hand, this may lead to a beneficial thermal path for the electronic component (for example a high-power high-voltage gallium nitride chip, for instance parallelized). Moreover, the inorganic carrier may provide a reliable electrical isolation, in particular to an optional exterior heat sink. Furthermore, the described arrangement may lead to a highly advantageous stray inductance, in particular since wire bonds may be reduced or even eliminated, and/or an eddy current compensation may be achieved. Exemplary embodiments may also provide a beneficial routing resulting in low electric losses. Moreover, the arrangement with the electrically conductive lateral thickening structure may lead to a high current capability of the package. Advantageously, the combination of a thinner pattern on the inorganic carrier and a thicker lateral thickening structure may allow a simple and accurate patterning process (in particular by etching) while at the same time ensuring high electrical (and in particular also high thermal) conductivity. Thus, reliability and performance of the obtained package may be excellent. Furthermore, a match between the pads of the electronic component and the patterned layer on the inorganic carrier may be advantageous.

### BRIEF DESCRIPTION OF THE DRAWINGS

The accompanying drawings, which are included to provide a further understanding of exemplary embodiments and constitute a part of the specification, illustrate exemplary embodiments. In the drawings:

FIG. 1 shows a cross-sectional view of a package according to an exemplary embodiment.

FIGS. 2 -FIG. 6 show structures obtained during carrying out a method of manufacturing a package, shown in FIG. 1, according to an exemplary embodiment.

FIG. 7 shows a plan view of a package according to another exemplary embodiment.

FIG. 8 shows a plan view of the package according to FIG. 7 without top-sided metal plate.

FIG. 9 shows a schematic cross-sectional view of the package according to FIG. 7 along a line A-A’.

FIG. 10 shows a schematic cross-sectional view of the package according to FIG. 7 along a line B-B’.

FIG. 11 shows another cross-sectional view of the package according to FIG. 7.

FIG. 12 shows a side view of the package according to FIG. 7.

FIG. 13 shows a plan view of the package according to FIG. 7.

FIG. 14 shows a cross-sectional view of a package according to another exemplary embodiment.

FIG. 15 shows a three-dimensional view of a bottom side of the package according to FIG. 14.

FIG. 16 shows a three-dimensional view of a top side of the package according to FIG. 14.

FIG. 17 shows a cross-sectional view of a package according to another exemplary embodiment.

FIG. 18 shows a three-dimensional view of the package according to FIG. 17.

FIG. 19 shows a cross-sectional view of the package according to FIG. 17.

FIG. 20 shows a cross-sectional view of a package according to another exemplary embodiment.

FIG. 21 shows a three-dimensional view of a top side of the package according to FIG. 20.

FIG. 22 shows a three-dimensional view of a bottom side of the package according to FIG. 20.

### DETAILED DESCRIPTION

The illustrations in the drawings are schematic. Before describing further exemplary embodiments in further detail, some basic considerations will be summarized based on which exemplary embodiments have been developed. In the following, further exemplary embodiments of the package and the method will be explained.

In the context of the present application, the term “package” may particularly denote a device which may comprise for example one, two or more chips. For example, at least part of the latter may be mounted on a carrier. Said constituents of the package may be optionally encapsulated at least partially by an encapsulant. Furthermore, an electric connection structure may form part of the package.

In the context of the present application, the term “carrier” may particularly denote a support structure which serves as a mechanical support for one or more electronic chips to be mounted thereon, and which may also contribute to the electric interconnection between the electronic chip(s) and the periphery of the package. In other words, the carrier may fulfil a mechanical support function and an electric connection function. A carrier may comprise or consist of a single part, multiple parts joined via encapsulation or other package components, or a subassembly of carriers.

In the context of the present application, the term "inorganic carrier" may particularly denote a carrier comprising an inorganic substance or material, in particular as main constituent. An inorganic substance may be a chemical compound that lacks carbon–hydrogen bonds. Thus, an inorganic compound is not an organic compound. For instance, the inorganic carrier comprises a ceramic material and/or a diamond material, in particular formed as a plate. Examples for an inorganic carrier are carriers comprising a base body comprising a ceramic (for instance aluminum nitride, silicon nitride, aluminum oxide), diamond (for instance monocrystalline or polycrystalline), glass, etc. An example for an inorganic carrier is a carrier comprising a sheet or plate made of an inorganic material and being covered on one or both opposing main surfaces thereof with a metal layer, wherein such a metal layer may be patterned or continuous. It is for example possible that the mentioned carrier is a DAB (Direct Aluminum Bonding) substrate, a DCB (Direct Copper Bonding) substrate, etc. Moreover, the carrier may also be configured as Active Metal Brazing (AMB) substrate.

In the context of the present application, the term “chip” may in particular denote an electronic component comprising a substrate in which at least one integrated circuit element is formed. For instance, the chip may be a semiconductor chip (in particular a power semiconductor chip). The chip may be an active electronic device. In particular, the chip may be a semiconductor chip having at least one integrated circuit element (such as a monolithically integrated transistor) in a surface portion thereof. Said surface portion may be denoted as active region of the chip. The chip may be a bare die or may be already packaged or encapsulated. Semiconductor chips implemented according to exemplary embodiments may be formed for example in silicon technology, gallium nitride technology, silicon carbide technology, etc.

In the context of the present application, the term “flip-chip configuration” may particularly denote a configuration of a chip in which the chip is mounted on a carrier with its active region and/or pads facing the carrier. The active region of the chip may be a surface region in which at least one integrated circuit element is integrated, in particular monolithically integrated. In a flip-chip attachment or arrangement, the chip or die may be attached to the carrier using a flip-chip method. The front side of the chip may face the carrier in a flip-chip configuration, whereas the back side of the chip may oppose the carrier.

In the context of the present application, the term “electrically conductive lateral thickening structure” may particularly denote a structure made of an electrically conductive material such as a metal which is located at least partially sideways or laterally of the electronic component including its pads. In particular, the lateral thickening structure may extend vertically along at least part of a sidewall of the electronic component. For instance, the lateral thickening structure may extend vertically over the entire extension of the sidewall, or over at least 50% of the height of the sidewalls. The lateral thickening structure may be locally thickened in a vertical direction with respect to another electrically conductive region, such as a patterned metal layer, with which said lateral thickening structure may be connected.

In the context of the present application, the term “main surface” of a body may particularly denote the largest body surface or one of the largest body surfaces. For instance, a body (such as a chip or a carrier) may be plate-shaped or substantially plate-shaped and may then have two opposing main surfaces separated by body material in a thickness direction and connected with each other by a circumferential edge.

In an embodiment, the pattern has a thickness in a range from 5 µm to 50 µm, in particular in a range from 10 µm to 30 µm. Additionally or alternatively, the lateral thickening structure has a thickness in a range from 100 µm to 800 µm, in particular in a range from 200 µm to 500 µm. More generally, a thickness of the lateral thickening structure may be larger than a thickness of the pattern. Thus, a fine pitch of the pattern may be combined with a high current carrying capability of the lateral thickening structure.

In an embodiment, the electronic component is a lateral chip, in particular a lateral power chip, for example a gallium nitride chip. In the context of the present application, the term “lateral chip” may particularly denote a chip being configured as a lateral device. This may be in contrast to a vertical device. Such a lateral chip may be configured so that, during operation, charge carriers flow along (or flow predominantly along) a lateral or horizontal direction (in particular rather than along a vertical direction). In contrast to vertical chips, the dominant current flow of lateral chips may be in a direction within a horizontal plane, in particular in parallel to a semiconductor substrate surface. For instance, all chip pads or terminals of a lateral chip may be on the same main surface of the chip. Due to the flip-chip configuration of an electronic component of a package according to an exemplary embodiment, all chip terminals may be on the front side of the chip facing the pattern on the inorganic carrier. Advantageously, a gallium nitride (GaN) chip may be realized in lateral device technology. Such a lateral device may generate heat during operation only on one main surface thereof, which may simplify heat removal by focusing on said region.

In an embodiment, the electronic component is a transistor chip, in particular a field-effect transistor chip. In the context of the present application, the term “transistor chip” may in particular denote a chip, such as a semiconductor chip, in which at least a transistor may be integrated, in particular monolithically integrated. Optionally, the chip may comprise at least one further integrated circuit element, such as a diode or a further transistor. In particular, a respective chip with integrated transistor may be a field-effect transistor chip having a source terminal (or pad), a drain terminal (or pad) and a gate terminal (or pad). Alternatively, a respective chip with integrated transistor may be a bipolar transistor chip having an emitter terminal (or pad), a collector terminal (or pad) and a base terminal (or pad). Specific examples of the transistor chips are a metal oxide semiconductor field effect transistor (MOSFET), and an insulated-gate bipolar transistor (IGBT).

In an embodiment, the electronic component is a power chip, in particular a semiconductor power chip. In the context of the present application, the term “power chip” may in particular denote a chip, such as a semiconductor chip, configured for a power application, for instance a power switching application. In an embodiment, the chip(s) with transistor is/are configured as power semiconductor chips. Thus, a corresponding chip (such as semiconductor chip) may be used for power applications for instance in the automotive field. Corresponding integrated circuit elements may be made for instance in silicon technology or based on wide-bandgap semiconductors (such as silicon carbide, gallium nitride or gallium nitride on silicon). A semiconductor power package may comprise one or more inverter circuits, one or more half bridges, one or more full-bridges, one or more drivers, one or more logic circuits, etc.

In an embodiment, a lateral dimension of a gap between adjacent ones of the pads is substantially the same as a lateral dimension of a gap between two adjacent elements or sections of the electrically conductive pattern. Additionally or alternatively, each of the pads is substantially fully overlapping with a corresponding one of elements or sections of the electrically conductive pattern. Thus, the arrangement of the pads on a main surface of the electronic component and the arrangement of the elements or sections of the pattern connected with such pads may be aligned or provided matching to each other. In particular, gaps between pads and gaps between elements or sections of the pattern may be spatially aligned. Preferably, gaps between pads and gaps between elements or sections of the pattern may have the same size, or the size may differ by less than 10%. Such an alignment or matching between pads and elements or sections of the pattern and/or of the gaps in between may lead to short electric paths, and low losses.

A good match between pads of a chip and a pattern of a DCB may bring the technical effects of a big electrical contact area, which may be especially good for high current applications. Moreover, a big thermal contact area, and a good mechanical support for the chip may be achieved as well to avoid extra stress on the pads of chip.

In an embodiment, the lateral thickening structure comprises at least one of a leadframe structure, a galvanic plating structure, or a metallic paste structure. In the context of the present application, the term “leadframe” may particularly denote a sheet-like metallic structure which can be bent, punched and/or patterned so as to form leadframe bodies as lateral thickening structure, and optionally connection leads for electric connection of the package to an electronic environment. In an embodiment, the leadframe may be a metal plate (in particular made of copper) which may be patterned, for instance by stamping or etching. Elements of such a leadframe structure may simply be placed laterally adjacent to the flip-chip mounted electronic component and connected with the pattern on the main surface of the inorganic carrier. However, the lateral thickening structure may also be embodied as galvanic plating structure formed by carrying out one or more electroplating stages. When providing the lateral thickening structure from a metallic paste, its shape and dimensions can be precisely controlled with low effort.

In an embodiment, the inorganic carrier has, opposing the main surface, a further main surface on or over which a conductive bulk structure is formed which has a thickness larger than a thickness of the pattern. Preferably, the inorganic carrier is made of an electrically insulating and thermally conductive material. Thermal conductivity of the inorganic carrier may be for example at least 20 W/mK, preferably at least 100 W/mK. When being electrically insulating and thermally conductive, the inorganic carrier may provide a reliable electric isolation barrier and heat removal capability. When attaching an electrically conductive bulk structure from a metallic material, such as copper or aluminum, which may be also thermally conductive, the thermal performance of the package may be further improved without compromising on electric reliability ensured by the inorganic carrier.

In an embodiment, the inorganic carrier has a heat dissipating metal layer directly on the further main surface and connected with the conductive bulk structure. For instance, both opposing main surfaces of the inorganic carrier may be covered with a respective metal layer, being the above-described pattern on one side and being the heat dissipating metal layer on the other side. In such a configuration, the inorganic carrier coated on both opposing main surfaces by metallic material may be embodied for instance as DAB (Direct Aluminum Bonding) or DCB (Direct Copper Bonding) substrate. The bottom surface of the inorganic carrier with its heat dissipating metal layer may be connected with the bulk structure, which may have a thickness bigger than a thickness of the pattern. The additional thin heat dissipation metal layer may be arranged between the inorganic carrier and the bulk structure. Said heat dissipation metal layer may have substantially the same thickness as the pattern.

In an embodiment, the conductive bulk structure has a thickness in a range from 100 µm to 800 µm, in particular in a range from 200 µm to 500 µm. Such a thick conductive, preferably electrically and thermally conductive, bulk structure may significantly improve the thermal performance of the package since it may contribute to remove heat from the main surface of the electronic component with its pads facing the pattern on the inorganic carrier.

For instance, the conductive bulk structure comprises a leadframe structure. More generally, the conductive bulk structure may comprise a metal plate structure.

In an embodiment, a thickness of the heat dissipating metal layer is substantially the same as a thickness of the pattern. Thus, the metal coating on the front side and the back side of the inorganic carrier defining the pattern and the heat dissipating metal layer, respectively, may be of uniform thickness.

In an embodiment, the package comprises an encapsulant encapsulating at least part of the electronic component and part of the lateral thickening structure. Optionally, the encapsulant may also encapsulate at least part of the inorganic carrier with its pattern. In the context of the present application, the term “encapsulant” may particularly denote a material, structure or member surrounding or intended for surrounding at least part of an electronic component, part of the lateral thickening structure and/or at least part of the inorganic carrier of the package. In this context, an encapsulant may provide mechanical protection and electrical insulation, and optionally a contribution to heat removal during operation. In particular, said encapsulant may be electrically insulating, for instance a mold compound. A mold compound may comprise a matrix of flowable and hardenable material, in particular a resin, optionally one or more additives, and optionally filler particles embedded therein. As an alternative to a mold compound (for example on the basis of epoxy resin), the encapsulant may also be a potting compound (for instance on the basis of an epoxy).

In an embodiment, a portion of the lateral thickening structure being exposed with respect to the encapsulant forms at least one lead. Thus, the package may be a leaded package. However, leadless packages may be possible as well in other embodiments. Advantageously, an exposed surface portion of the lateral thickening structure may allow to electrically connect the lateral thickening structure and thereby also the pads of the electronic component with an electronic periphery of the package. The exposed portion of the lateral thickening structure may be arranged at one or more sidewalls of the package and may protrude laterally beyond an encapsulant.

In an embodiment, a portion of the conductive bulk structure is exposed with respect to the encapsulant. Such an exposed surface of the preferably electrically and thermally conductive bulk structure may allow to efficiently dissipate heat out of the package. The exposed portion of the conductive bulk structure may form at least part of a bottom main surface of the package. It may be possible to attach a heat sink to the exposed portion of the conductive bulk structure, for further improving thermal performance.

In an embodiment, the package comprises an electrically insulating structure between adjacent ones of the pads and between corresponding adjacent sections of the pattern. In view of small dimensions of tiny gaps between pads and between sections of the pattern, it may be advantageous to provide an electrically insulating structure in such gaps for improving electrical reliability of the package. Even in the presence of manufacturing tolerances, such a gap-filling electrically insulating structure may ensure electric decoupling between adjacent pads and/or between adjacent elements of the pattern.

In an embodiment, a material of the encapsulant is different from a material of the electrically insulating structure. Thus, the electrically insulating structure may be provided apart from the encapsulant. Considering the very small size of the gaps, is may be difficult to fill the gap by a mold flow during an encapsulation. In such a scenario, it may be preferred to provide an extra process to fill the gaps with an extra material, such as an underfill material. Hence, a different underfill material compared with the encapsulant material may be beneficial in terms of electric reliability.

In another embodiment, a portion of the encapsulant forms the electrically insulating structure. For instance in a scenario in which gaps between adjacent pads and/or between adjacent elements of the pattern are not very small or difficult to access, encapsulant material may be also used for filling said gaps for ensuring electric separation between adjacent pads and/or elements of the pattern. This may then be possible without an additional process for forming the electrically insulating structure.

In an embodiment, the package comprises at least one further electronic component having further electrically conductive pads and being mounted in a flip-chip configuration on the carrier so that the further pads are electrically coupled with the pattern, wherein the electrically conductive lateral thickening structure is electrically coupled with at least part of the further pads. For example, this may be advantageous for providing a half bridge module. Thus, a plurality of electronic components of the above-described type may be electrically interconnected in the package. This may allow to provide even more sophisticated electronic functions, such as a half bridge function. For example, all electronic components of the package may be mounted in flip-chip configuration with its pads being electrically coupled with the pattern on the inorganic carrier. This may lead to a compact design and an efficient heat removal architecture.

In an embodiment, the electronic component and the at least one further electronic component are interconnected to form at least one half bridge. In the context of the present application, the term “half bridge” may particularly denote a circuit composed of an upper transistor switch (“high-side”) and a lower transistor switch (“low-side”) which are both controlled by a logic or control chip (or by a plurality of such logic or control chips). For instance, the transistors may be field-effect transistors. The transistors may be connected in a cascode arrangement. The two transistor switches may be turned on and off complementary to each other (in particular with a non-overlapping dead-time) by applying corresponding voltage waveforms at control terminals (such as gate terminals). The mentioned half bridge configuration may be used as such or alone or may be combined with one or more further half bridges (or other electric circuits) to realize a more complex electric function. For instance, two such half bridges may form a full bridge.

In an embodiment, the package comprises a metal plate above and extending over both the electronic component and the at least one further electronic component. For instance, such a metal plate may be interconnected to function as a direct current (DC) plate, in particular as a DC+ plate. For example, such a metal plate may be arranged on top of the electronic component and the at least one further electronic component without necessarily being in direct electric interconnection or physical contact with said electronic components.

In an embodiment, the package comprises a metal plate above at least one of the electronic component and the at least one further electronic component and being connected with the pattern by metallic plate connectors laterally enclosing the electronic component and the at least one further electronic component. For instance, such metallic plate connectors may be a metallic blocks connecting a direct current plate with the at least one electronic component.

In an embodiment, the package comprises a laminate carrier in which the inorganic carrier with the pattern, the electronic component with the pads and the lateral thickening structure are embedded. For example, this may be advantageous for chip embedding embodiments. In the context of the present application, the term “laminate” may particularly denote a flat body (such as a sheet or plate) formed by multiple interconnected laminate layers, i.e. layers which can be or which are interconnected by lamination. In particular, a laminate may comprise a material that is suitable for sticking several laminate layers, for instance made of the same material, together. Hence, a laminate may be a plate-shaped or sheet-shaped body made of one or multiple laminable or laminated layers. Said laminate layers may be connected or configured to be connectable with other layers by lamination. Lamination may denote a connection of laminable layers using elevated temperature, optionally accompanied by an additional mechanical pressure applied to stacked laminate layers. In particular, such a laminate may be a pressed multilayer stack of one or more dielectric organic layers and/or one or more metallic foils. One or more dielectric laminate layers may be for example prepreg layers. Prepreg is a material which comprises a resin, optionally with glass particles therein. The laminate may also comprise one or more metal layers, which may be copper foils. More generally, the laminate may comprise at least one dielectric layer which is capable of curing, polymerizing and/or cross-linking during a lamination process, thereby contributing to an adhesion force between multiple layers of a multilayer laminate. For instance, a laminate may be a chip substrate or a printed circuit board (PCB). By embedding the constituents of the package in a laminate substrate or carrier, the electric interconnection of the at least one electronic component may be further refined.

In an embodiment, the package comprises an encapsulant encapsulating, in an interior of the laminate carrier, at least part of the inorganic carrier with the pattern, the electronic component with the pads and the lateral thickening structure. Descriptively speaking, an encapsulant-in-encapsulant structure may be achieved, wherein for instance an interior encapsulant may be an epoxy-based mold compound, whereas an exterior encapsulant may be the organic laminate carrier.

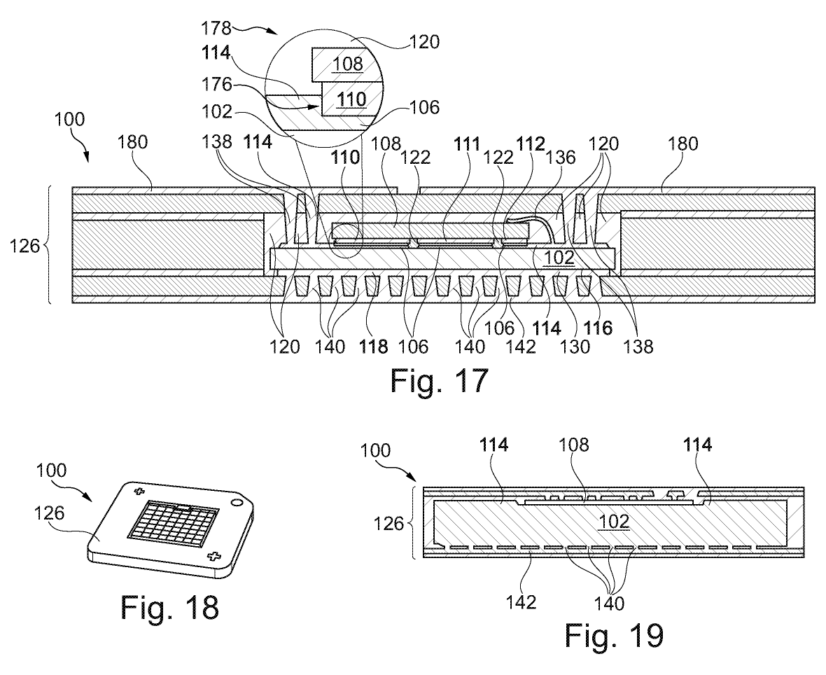

In an embodiment, the lateral thickening structure is electrically coupled with electrically conductive lateral vertical through connections between which the electronic component is arranged and which extend through the laminate carrier. Said “electrically conductive lateral vertical through connections” may be arranged laterally of the at least one electronic component and may extend in a vertical direction. For instance, such laterally arranged vertical through connections laterally enclosing the at least one electronic component may comprise metallic vias, see for example FIG. 17. For example, such vias may have a large aspect ratio, i.e. a ratio between vertical extension and horizontal diameter, of at least two. For instance, such chip-lateral vertical through connections may extend from the upper height level of the lateral thickening structure and may extend vertically at least over the entire vertical dimension of the electronic component. Hence, said chip-lateral vertical through connections may increase the metal content of the lateral thickening structure sideways from the electronic component and may therefore further improve the electrical current carrying capability. When the chip-lateral vertical through connections even extend up to an exterior metal layer (such as a copper foil) at an upper main surface of the package, very short connection paths may be further promoted.

In an embodiment, the package comprises thermally conductive vertical through connections extending from a bottom side of the inorganic carrier through the laminate carrier up to a bottom main surface of the package, in particular up to an exterior metal layer at the bottom main surface of the package. Such thermally conductive vertical through connections may be metal filled vias transporting heat away from the inorganic carrier towards a lower main surface of the package.

In an embodiment, a lateral spacing between adjacent sections of the pattern is in a range from 3 µm to 40 µm, in particular in a range from 5 µm to 20 µm. Correspondingly, a lateral spacing between adjacent pads of the electronic component may be in a range from 3 µm to 40 µm, in particular in a range from 5 µm to 20 µm. In particular, said lateral spacings may be the same.

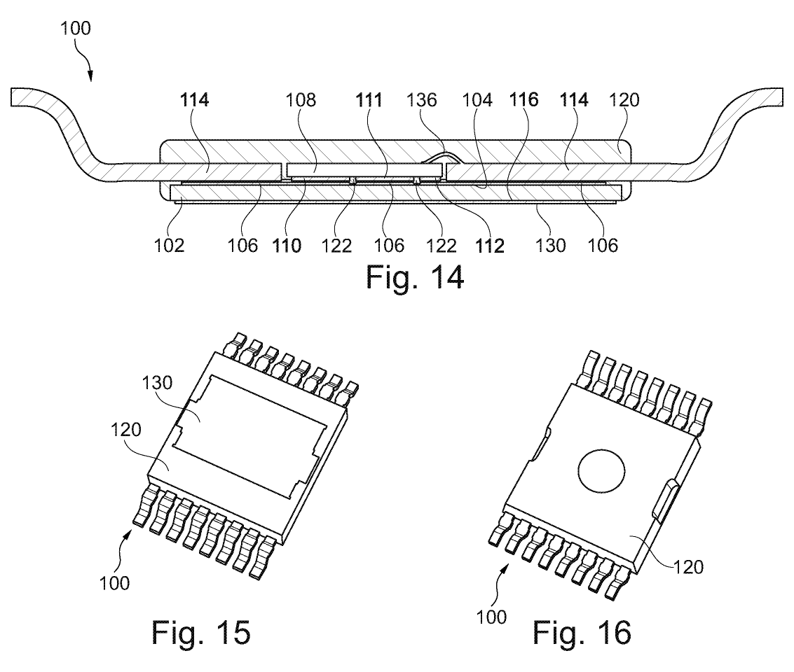

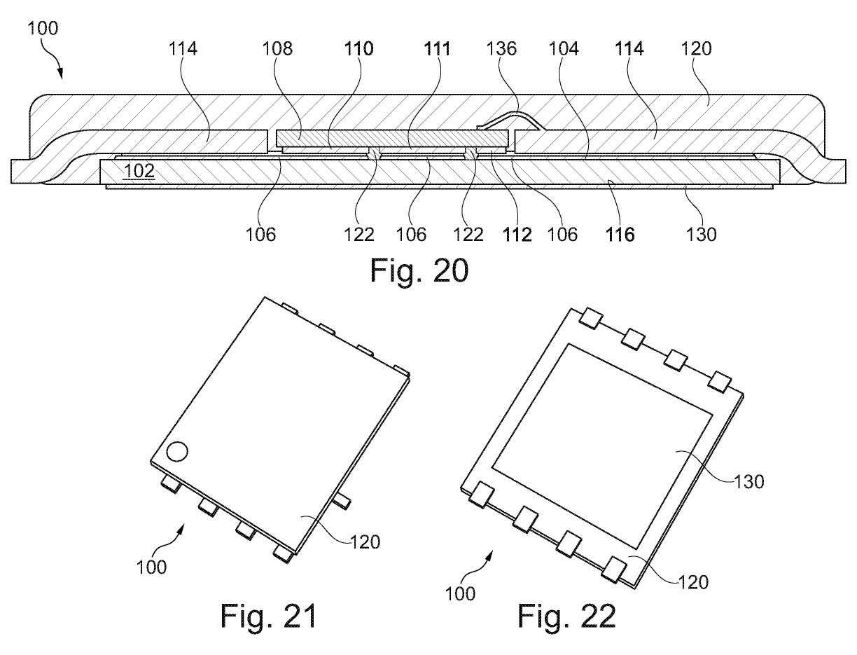

In an embodiment, the package is configured as a leaded package, for example a gullwing leaded package. Alternatively, the package may be configured as a leadless package. When referring to leaded and leadless packages, this may describe the fact whether or not the package has metal legs that can be mounted on a mounting base such as an electronic board (for instance a PCB). A leaded package may comprise exposed metallic legs (see for example FIG. 14), whereas a leadless package may be free of exposed metallic legs (see for example FIG. 20). In a leaded package design, portions of the thickening structure may be exposed with respect to an encapsulant so as to form leg-shaped leads of the leaded package. In a leadless package, only surface portions of the thickening structure may be exposed with respect to an encapsulant without forming a leg-shaped lead extending out of the encapsulant.

In an embodiment, the lateral thickening structure is thermally conductive. Thermal conductivity of the lateral thickening structure may be for example at least 20 W/mK, preferably at least 100 W/mK.

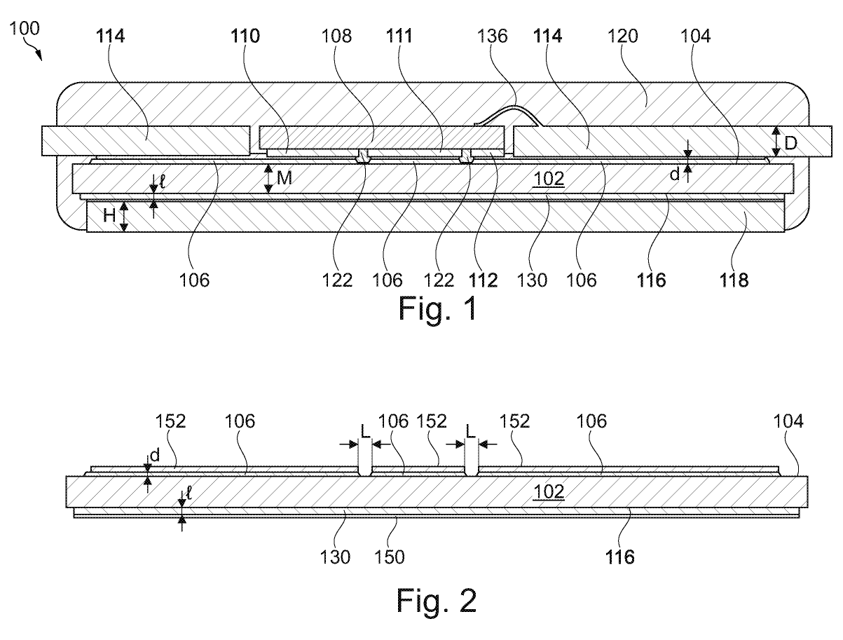

In an embodiment, the package comprises a bond wire having a first end connected to a back side of the electronic component and another second end connected to the thickening structure. Besides connecting to the thickening structure, it may also be possible that the bond wire or another bond wire connects the pattern. In the context of the present application, the term “bond wire” may particularly denote an electrically conductive filament, wire or thread. In an assembled configuration, the bond wire may extend in a curved fashion, or straight. A bond wire may be made of a metallic material, such as aluminum, copper, silver and/or gold. For instance, a bond wire may have a diameter in a range from 5 µm to 700 µm, in particular in a range from 10µm to 500 µm. For example, a bond wire may have a length of at least 500 µm or of at least 1 mm, in particular of at least 3 mm or of at least 10 mm. For example, a bond wire may have a round (in particular circular) or polygonal (in particular rectangular) cross-section, or may be embodied as a bond ribbon. The bond wire (see reference sign 136 in FIG. 1) may have one end connected to the back side of the electronic component (which may be a gallium nitride die) and another end connected to the thickening structure. In such an embodiment, the electronic component may be directly bonded to the thinner pattern, and the bond wire may be directly bonded to the thicker thickening structure. Bond wire may then avoid a floating substrate.

In an embodiment, the package is configured as one of the group consisting of a leadframe connected power module, a Transistor Outline (TO) package, a Quad Flat No Leads Package (QFN) package, a Small Outline (SO) package, a Small Outline Transistor (SOT) package, and a Thin Small Outline Package (TSOP) package. Therefore, the package according to an exemplary embodiment is fully compatible with standard packaging concepts (in particular fully compatible with standard TO packaging concepts) and may appear externally as a conventional package, which is highly user convenient.

In an embodiment, the package comprises a plurality of electronic components, in particular semiconductor components, encapsulated by the encapsulant. Thus, the package may comprise one or more semiconductor components (for instance at least one passive component, such as a capacitor, and at least one active component).

As substrate or wafer forming the basis of the chip(s), a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

For gallium nitride-type field-effect transistor chips, power loss may be generated purely or at least predominantly at the front side of the device. Conventionally, cooling of the device is done through its back side, i.e. the heat has to be transported through the relatively thick carrier silicon. This may result conventionally in an inefficient thermal path with high thermal resistance and a reduced ability to cool short-term power spikes.

Moreover, conventional packages with ceramic substrate need to carry high currents and therefore have a relatively thick copper layer, which does not allow for fine design rules between isolated areas of metal which are generated by etching grooves into the copper by a wet etch process. At the top, those grooves may be relatively wide (for instance in a range from 1 mm to 2 mm). In a gallium nitride chip being embodied as a lateral device, there may be at least three electrical potentials to be connected separately. If chips are mounted flipped, most of the area would be over those etched grooves without any cooling. One issue may be poor cooling, another issue may be a smaller area for electrical connection, both because only part of the pad area connects the underneath copper layer of the DCB or AMB. In a conventional package with ceramic substrate, a flip-chip mounted chip may suffer from a poor thermal path due to wide etch grooves, so that significant areas of chip are not cooled at all.

According to an exemplary embodiment, a package can be manufactured on the basis of an inorganic carrier, for instance a ceramic carrier being electrically insulating and thermally highly conductive. An electrically conductive pattern or structure may be formed on a main surface of the inorganic carrier, so that pads of at least one electronic component may be assembled on said electrically conductive pattern promoting short electric paths. The at least one electronic component may be mounted on the pattern on the inorganic carrier in a flip-chip manner in which an active region of the electronic component may face the inorganic carrier. This may also contribute to short electric paths. Beyond this, an electrically conductive lateral thickening structure may extend in a vertical direction parallel to at least a portion of sidewalls of the at least one electronic component which may also promote a low ohmic electric connection while simultaneously contributing to heat removal out of the package. Exemplary embodiments may provide a beneficial thermal path for the electronic component, in particular when embodied as power semiconductor chip. In addition, the inorganic (preferably ceramic) carrier may combine a reliable electrical isolation with a high thermal conductivity, which may lead to electric reliability and good thermal performance. By integrating the electrically conductive pattern and the connected electrically conductive lateral thickening structure in a path for electrically contacting chip pads of the at least one electronic component, high signal integrity may be combined with excellent thermal performance. Moreover, such an electric connection architecture may reduce stray inductance, as the number of wire bonds may be at least strongly reduced. To put it shortly, an efficient routing may be combined with a high current capability and good heat removal capability of the package.

There is a current trend that electronic components (such as gallium nitride dies) become smaller and smaller. Therefore, the distance between adjacent pads of the electronic component (in particular drain and source pads) becomes smaller and smaller. The pattern (gap L in FIG. 2) on the inorganic carrier (for example of a DCB, direct copper bonding substrate) may be made by etching. A current etching has a limitation that, when etching a thick metal (in particular copper) layer of a DCB or another kind of inorganic area, the gap may also be big. In order to overcome such shortcomings, an exemplary embodiment may implement a thin metallic pattern (for instance a thin copper pattern) underneath the electronic component. Then, it may be easily possible to pattern (in particular by etching) such a metal layer for forming the pattern with a small gap between adjacent elements of the pattern. Such a small gap may be similar or identical to the distance between adjacent pads of the electronic component (for example between drain and source pads). Consequently, said pads can land or at least substantially land on the assigned elements of the pattern. As to the lateral thickening structure having a larger thickness that the thinner pattern, this may have a positive impact on electrical and thermal functionality. More specifically, a thin copper pattern (for instance having a thickness in the range of 5 µm to 50 µm or 10 µm to 30 µm) may be provided for matching the distance of drain and source pads of a gallium nitride die. In particular, the combination of such a thin copper layer underneath the die and a thick copper component laterally adjacent the die may be of utmost advantage. Preferably, the gap between two patterned parts of the thin layer and the distance between source and drain pads of the die may be substantially the same.

Advantageously, an exemplary embodiment provides flip-chip mounted electronic components, for instance gallium nitride transistor chips on a ceramic substrate. For thermal reasons, flip-chip mounting has a significant advantage. For high voltage devices, it may be advantageous to assemble one or more electronic components on an inorganic, preferably ceramic, substrate or carrier for advantageous or even optimum thermal performance. A (for example ceramic or diamond) inorganic carrier or substrate with a thin metal layer thereon may be structured such that the obtained electrically conductive pattern provides elements or pads with the same size as the pads of the flip-chip type electronic component for advantageous or even optimum thermal and electrical interconnection. Those elements or pads of the electrically conductive pattern may be extended on the inorganic carrier or substrate beyond the flip-chip type electronic component to provide the electrical interconnect to the outside. The at least one electronic component may be flip-chip mounted on those elements or pads (for example by solder bumps, sinter glue, diffusion solder, etc.). Outside of the electronic component, the metal layers on the inorganic carrier or substrate may be thickened by a metal such as copper. For example, this may be achieved by attaching bulk copper (for instance a leadframe), by galvanic deposition and/or by printing thick copper paste. In particular when a leadframe is used for providing the lateral thickening structure, it may also provide terminals to the outside. To provide efficient electric isolation, it may be advantageous that grooves between the elements or pads are electrically isolated, for example by an organic compound like an underfill material.

Since electronic components such as chips become smaller and smaller, the matching between the pads of chips and the underlying substrate (e.g., DBC, AMB, etc.) may become a challenge, especially when the substrate is made by etching, where the thickness of a metal layer of the substrate may play an important role in the etching process. Exemplary embodiments may address such challenges, in particular by providing a lateral thickening structure and/or by matching a pattern with pads of an electronic component.

More specifically, a gallium nitride chip-type electronic component with heat generation on the front side may be mounted on a ceramic substrate with fine pitch metallization. A leadframe may be added to provide an electrically conductive lateral thickening structure capable of carrying a high amount of electric current.

Exemplary embodiments may also be used in the context of flip-chip mounting of silicon carbide (SiC) and silicon (Si) based power devices. In a preferred embodiment, the package may be a gallium nitride (GaN) based high power module. In particular, a package according to an exemplary embodiment may be a high voltage gallium nitride top-side cooled isolated discrete package. However, another exemplary embodiment may be a silicon carbide (SiC) based high power module with strong suppression of parasitic phenomena. A package according to an exemplary embodiment may comprise electronic components connected as half bridge.

The above and other objects, features and advantages of the present invention will become apparent from the following description and the appended claims, taken in conjunction with the accompanying drawings, in which like parts or elements are denoted by like reference numbers.

FIG. 1 shows a cross-sectional view of a package 100 according to an exemplary embodiment.

The illustrated package 100 comprises a plate-shaped inorganic carrier 102, which may be made of a ceramic material such as aluminum nitride. The inorganic carrier 102 may have an upper main surface 104 at which an electrically conductive pattern 106 is formed, for instance made of copper. The electrically conductive pattern 106 may be a planar structured metal layer. Furthermore, the inorganic carrier 102 has a continuous heat dissipating metal layer 130, for instance made of copper, directly on a lower main surface 116 of the inorganic plate. Heat dissipating metal layer 130 may be for avoiding warpage during the manufacturing of the conductive bulk structure 118, for instance based on FIG. 2. For example, the pattern 106 has a thickness d in a range from 5 µm to 50 µm. A thickness l of the heat dissipating metal layer 130 may be the same as the thickness d of the pattern 106. For example, the heat dissipating metal layer 130 has a thickness l in a range from 5 µm to 50 µm. For instance, the inorganic plate of the inorganic carrier 102 to may have a thickness M in a range from 50 µm to 2000 µm.

An electronic component 108 is provided, which may be a semiconductor die. For instance, said semiconductor die may be a gallium nitride die. The electronic component 108 may be a lateral device experiencing a substantially horizontal current flow during operation and having all its functionally active electrically conductive terminals or pads 110-112 on the same main surface, which is the lower main surface according to FIG. 1. In the shown embodiment, the electronic component 108 may be a transistor die, more specifically a field-effect transistor die. For example, pad 110 may be a source pad, pad 111 may be a drain pad and pad 112 may be a gate pad. In the shown embodiment, the electronic component 108 may provide a power function and may carry high electric current during operation.

The electronic component 108 with its electrically conductive pads 110-112 all on the same main surface of the chip may be mounted in a flip-chip configuration on the inorganic carrier 102. This assembly may be accomplished in such a way that all pads 110-112 are electrically coupled with the pattern 106. More specifically, each of pads 110-112 may be electrically coupled with an assigned one of separate elements or sections of the pattern 106. As shown in FIG. 1, each of the pads 110-112 is fully overlapping with a corresponding one of elements of the electrically conductive pattern 106. For example, an extension of each respective pad 110-112 in the horizontal plane does not protrude or does not protrude noteworthy beyond an extension of the assigned and connected element or section of the pattern 106. Gaps between adjacent pads 110-112 may be aligned with and may be dimensioned as gaps between adjacent elements or sections of the electrically conductive pattern 106. Each of the pads 110-112 may be electrically and mechanically connected with a corresponding one of the elements or sections of the pattern 106, for example by soldering, sintering or an electrically conductive glue.

As shown, an electrically insulating structure 122 is provided between adjacent ones of the pads 110-112 and between corresponding adjacent sections of the pattern 106 for reliably electrically decoupling adjacent pads 110-112 and adjacent sections of the pattern 106 from each other. In the shown embodiment, a material of a below described mold compound-type encapsulant 120 is different from a material of the electrically insulating structure 122, which may be a separate dielectric thermal underfill. By filling the gaps between adjacent pads 110-112 and between adjacent elements of pattern 106 with the electrically insulating structure 122, a reliable electrically decoupling may be ensured even when a mold flow into the tiny gaps during encapsulation would be insufficient to completely and reliably fills said gaps. In a scenario with sufficiently large gaps or with properly accessible gaps, it may also be possible that a portion of the encapsulant 120 forms the electrically insulating structure 122. Advantageously, the electrically insulating structure 122 keeps the different electric potentials of the different pads 110-112 separate, in particular electrically isolates the source pad from the drain pad.

Still referring to FIG. 1, package 100 further comprises an electrically conductive lateral thickening structure 114 arranged laterally from the electronic component 108 and being electrically coupled with the pads 110-112. For instance, the lateral thickening structure 114 comprises copper. For example, the lateral thickening structure 114 may be embodied as a leadframe structure, a galvanic plating structure, and/or a metallic paste structure. As shown, the lateral thickening structure 114 extends vertically from the pattern 106 (which extend laterally beyond the electronic component 108) over part of or even over the entire vertical extension of the electronic component 108, optionally even protruding vertically beyond an upper main surface of the electronic component 108. The electronic component 108 may be laterally arranged between two or more different substructures of the lateral thickening structure 114, or may be even circumferentially surrounded by an annular lateral thickening structure 114. Preferably, the lateral thickening structure 114 has a thickness D in a range from 100 µm to 800 µm. Thus, the thickness D of the lateral thickening structure 114 may be significantly larger than the thickness d of the pattern 106. Advantageously, the lateral thickening structure 114 may be electrically conductive and thermally conductive. Consequently, the lateral thickening structure 114 may ensure a high current carrying capability of the package 100, and may also contribute to the thermal performance of the package 100.

Moreover, package 100 according to FIG. 1 comprises a bond wire 136. A first end of bond wire 136 is connected to a back side of the electronic component 108, i.e. to a main surface of the electronic component 108 facing away from its front-sided pads 110-112. Another second end of the bond wire 136 is connected to the thickening structure 114. Alternatively, it may be possible to connect the bond wire 136 to pattern 106. The electrically conductive bond wire 136 connects the substrate and thereby prevents a floating substrate.

As shown in FIG. 1 as well, the inorganic carrier 102 has, opposing its main surface 104, its further main surface 116 over which a conductive bulk structure 118 is formed. More specifically, the inorganic carrier 102 has directly on its bottom main surface 116 the heat dissipating metal layer 130. Said metal layer 130 is connected with the conductive bulk structure 118, for instance with a connection medium, such as solder or sinter material, in between. Hence, the metal layer 130 is arranged between the inorganic plate of inorganic carrier 102 and the bulk structure 118. Preferably, conductive bulk structure 118 is electrically and thermally conductive, for instance is embodied as a metal plate or sheet. For instance, said bulk structure 118 may be made of copper or aluminum. For example, the conductive bulk structure 118 comprises a leadframe structure. Thus, the bulk structure 118 may contribute to the thermal performance of package 100. While the electrically insulating and thermally conductive inorganic plate of inorganic carrier 102 may electrically insulate the bottom side of package 100, the stacking of electrically and thermally conductive bulk structure 118 on the bottom side of the inorganic plate extending out of the encapsulant 120 may promote heat removal out of package 100 at its bottom side without compromising electric reliability. For this purpose, it may be advantageous that the conductive bulk structure 118 is provided with a large thickness H, for instance in a range from 100 µm to 800 µm.

Moreover, package 100 comprises encapsulant 120 encapsulating the entire electronic component 108, part of the lateral thickening structure 114, the entire inorganic carrier 102, the entire bond wire 136 and part of the conductive bulk structure 118. In particular, encapsulant 120 may be a mold compound, in particular an epoxy mold compound, which may have fillers (for instance for enhancing thermal conductivity of encapsulant 120) therein. As shown in FIG. 1, a lateral portion of the lateral thickening structure 114 is exposed with respect to the encapsulant 120 so as to form an electrically conductive surface or even electrically conductive leads on two opposing sidewalls of the encapsulant 120. Furthermore, a bottom main surface of the plate-shaped electrically and thermally conductive bulk structure 118 is exposed with respect to the encapsulant 120. This may promote dissipation of heat generated on a bottom side of the electronic component 108 during operation out of the package 100 via conductive bulk structure 118. Furthermore, the exposed metallic surface of the conductive bulk structure 118 may allow connecting a heat sink (not shown), for instance by soldering, on the bottom side of the package 100.

FIGS. 2- FIG. 6 show structures obtained during carrying out a method of manufacturing a package 100, shown in FIG. 1, according to an exemplary embodiment.

Referring to the cross-sectional view of FIG. 2, inorganic carrier 102 is shown with its central ceramic plate and the electrically conductive pattern 106 on main surface 104 as well as metal layer 130 on opposing main surface 116. Both the electrically conductive pattern 106 as well as the continuous metal layer 130 may be a very thin metallization layer, for instance having a thickness of not more than 50 µm. Thus, fine pitch structures may be formed. As shown as well in FIG. 2 and FIG. 3, a lateral dimension of a gap B between adjacent ones of the pads 110-112 may be the same or substantially the same as a lateral dimension of a gap L between two adjacent elements of the electrically conductive pattern 106. For instance, such a lateral spacing L or gap width between adjacent sections of the pattern 106 may be in a range from 3 µm to 40 µm. Correspondingly, a lateral spacing B or gap width between adjacent pads 110-112 of the electronic component 108 may be in a range from 3 µm to 40 µm. By etching, such very small gaps L or openings may be created in the pattern 106. As a rule of thumb, said lateral spacing L may be dimensioned in accordance with a thickness of the electronic component 108 mounted on the inorganic carrier 102 later.

Optionally, a plating layer 150, 152 (for instance made of Ni/Sn) may be formed or pre-plated on any of electrically conductive pattern 106 and metal layer 130. For instance, such a plating layer 150, 152 may promote solderability.

Referring to the cross-sectional view of FIG. 3, electronic component 108 may be surface mounted in a flip-chip configuration on the pattern 106 so that each of pads 110-112 arranged all on the same bottom main surface of the electronic component 108 is electrically coupled with a respective one of the elements of pattern 106. Moreover, electrically and thermally conductive lateral thickening structure 114 is mounted vertically on lateral extensions of the pattern 106 so that electronic component 108 is arranged laterally between substructures of lateral thickening structure 114. In the shown embodiment, an upper main surface of the lateral thickening structure 114 is optionally in flush or is substantially in flush with the upper main surface of the electronic component 108. On a bottom main surface of the structure shown in FIG. 2, conductive bulk structure 118 is connected on metal layer 130. Any of the lateral thickening structure 114 and the conductive bulk structure 118 may be formed by a leadframe structure, for instance made of copper. The lateral thickening structure 114 may be configured for enhancing current carrying capability of the package 100. The conductive bulk structure 118 may be adapted for heat spreading during operation of the package 100.

To put it shortly, FIG. 3 shows the processes of a flip chip die attach, a leadframe attach and an optional copper heat spreader attach (for instance for promoting thermo-mechanical symmetry). Any of the connection tasks executed according to FIG. 3 may be realized in particular by any of diffusion soldering, sintering, or hybrid sintering.

As indicated by auxiliary indicators 156 and corresponding arrows in FIG. 3, the relative arrangement between the pads 110-112 and the elements of the pattern 106 may be variable. In any case, an overlap between a respective pad 110-112 and a corresponding element of pattern 106 should be preferably as large as possible. In particular, a full alignment between the gaps between adjacent pads 110-112 and between adjacent elements of pattern 106 may be preferred.

With the measures taken according to FIG. 3, a high thermal performance can be combined with high current capability and fine pitch routing capability. Thus, fine lines and spaces may be realized as pattern 106 in accordance with a pitch of pads 110-112. The lateral thickening structure 114 may carry a high current and may form leads extending out of the encapsulant 120 of package 100.

Referring to the cross-sectional view of FIG. 4, electrically insulating structure 122 is provided between adjacent ones of the pads 110-112 and between corresponding adjacent sections of the pattern 106. Electrically insulating structure 122 may be applied by dispensing it into the gaps between pads 110-112 and between elements of pattern 106. Electrically insulating structure 122 may be embodied for instance as thermal underfill dispense.

Thereafter, bond wire 136 may be connected as shown in FIG. 1, and the obtained structure may be subjected to encapsulation by encapsulant 120, for instance by molding (not shown).

Referring to the plan view of FIG. 5, electronic component 108 and inorganic carrier 102 are shown in a top view. More precisely, electronic component 108 shown on the left hand side is illustrated with its pads 110-112. As indicated by arrow 160, the electronic component 108 is turned upside down so that its pads 110-112 are assembled in a flip chip configuration on the pattern 106 formed on the top main surface of the inorganic carrier 102 shown in a central portion of FIG. 5. For example, a corresponding connection can be done by soldering. As shown on the right-hand side of FIG. 5, each of the pads 110-112 is connected with an assigned one of elements of pattern 106.

Referring to the plan view of FIG. 6, a leadframe structure composed of several (three in the shown embodiment) substructures is then connected to exposed portions of the several (three in the shown embodiment) elements of pattern 106. For instance, this can be accomplished by soldering. Thereby, the electrically conductive thickening structure (composed of three substructures in the shown embodiment) is formed.

Thereafter, encapsulation may be carried out, as indicated schematically by reference sign 120 in FIG. 6.

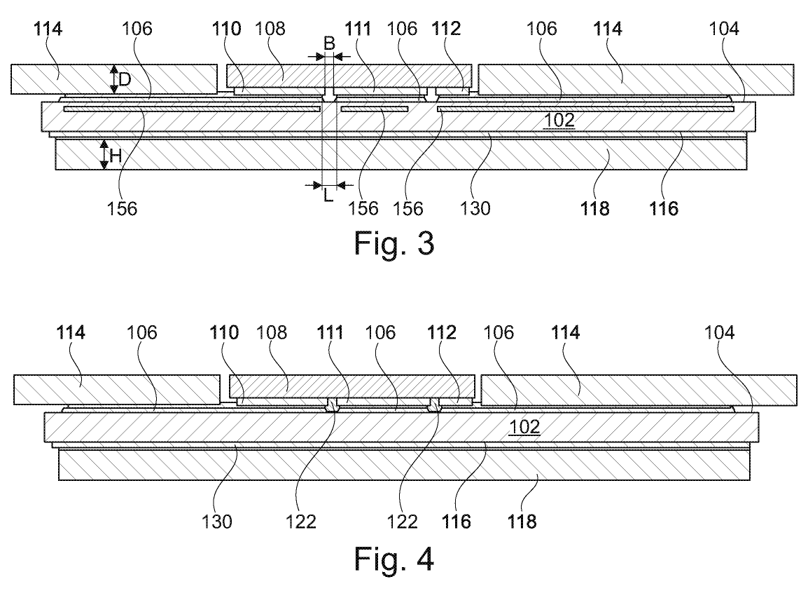

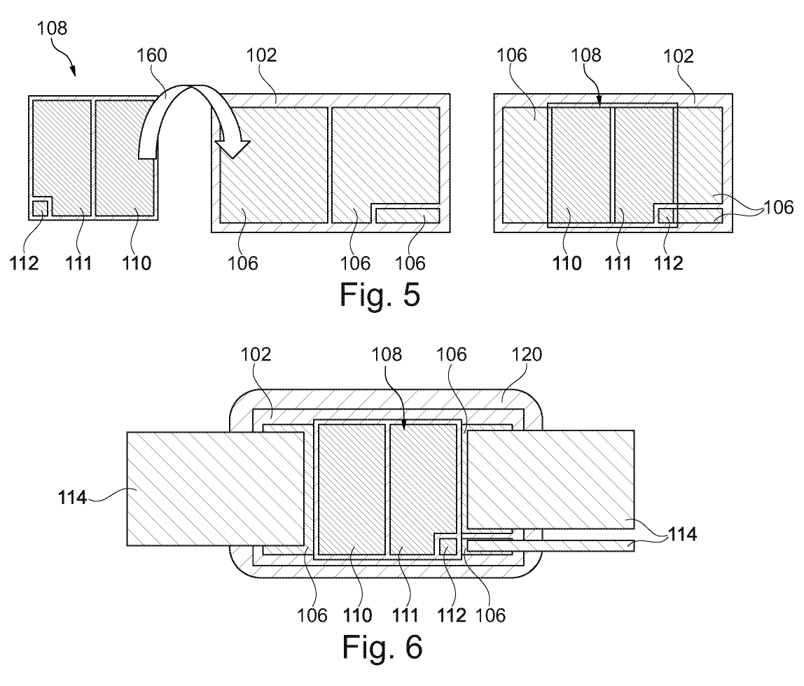

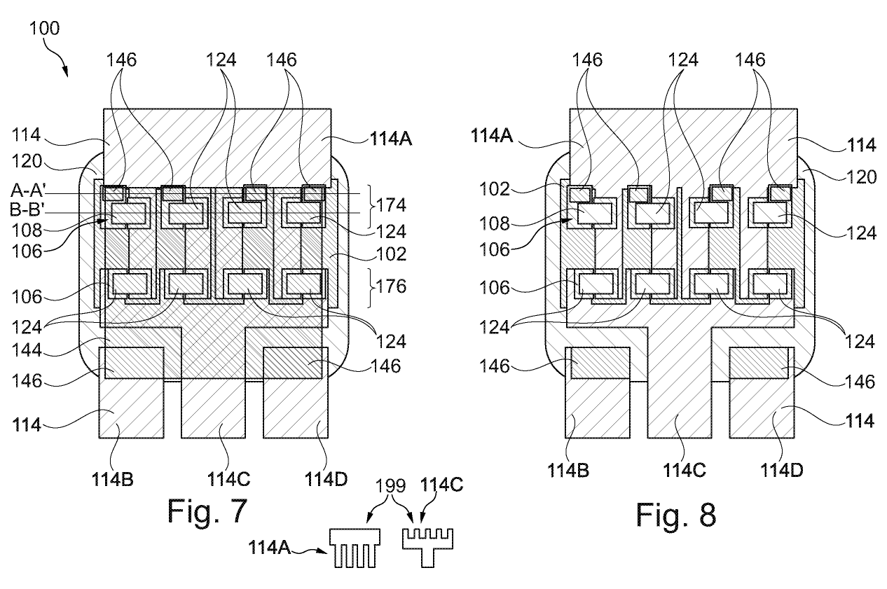

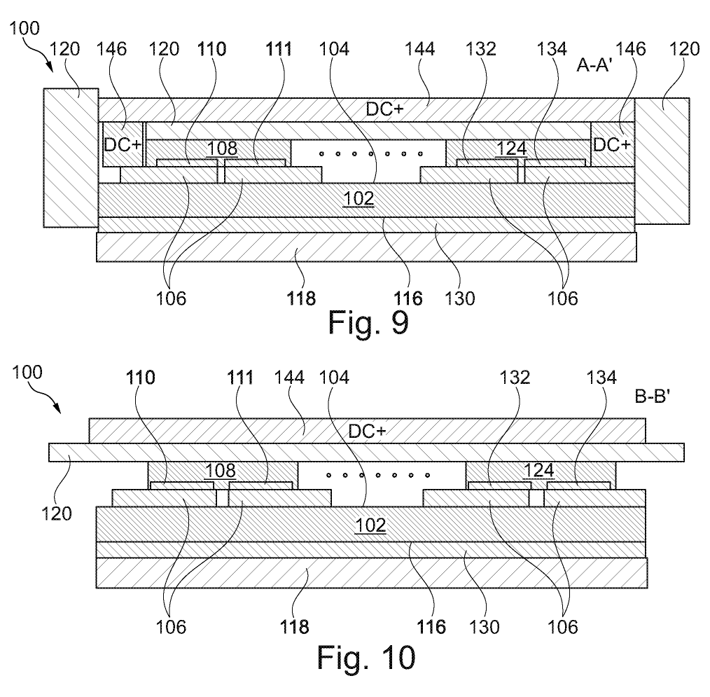

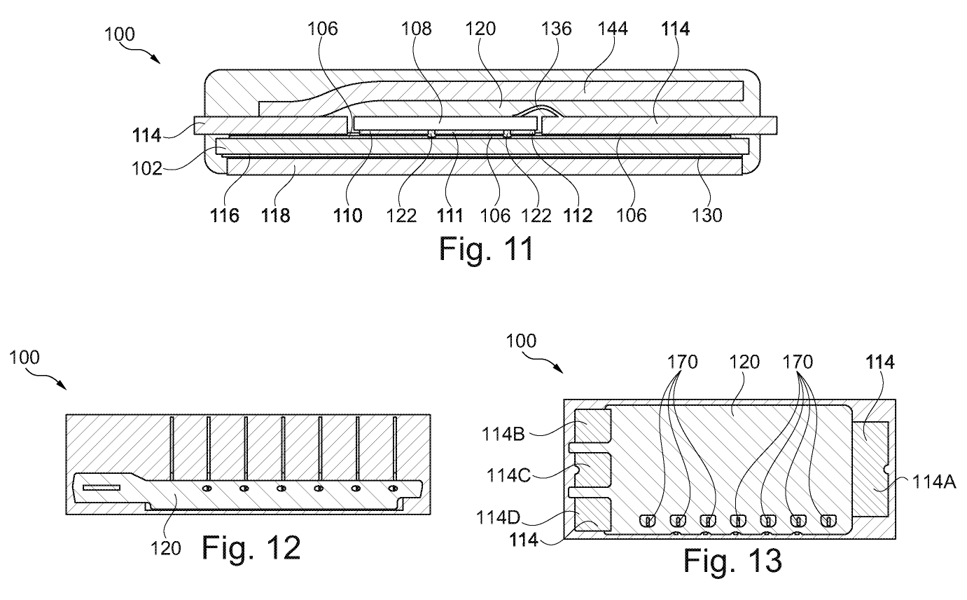

FIG. 7 shows a plan view of a package 100 according to another exemplary embodiment. FIG. 8 shows a plan view of the package 100 according to FIG. 7 without top-sided metal plate 144. FIG. 9 is a schematic view which shows a cross-section of the package 100 according to FIG. 7 along a line A-A’ (however, only two electronic components 108, 124 are shown in FIG. 9, whereas two further electronic components 124 in between are omitted in FIG. 9 for the sake of clarity). FIG. 10 is a schematic view which shows a cross-sectional view of the package 100 according to FIG. 7 along a line B-B’ (again, only two electronic components 108, 124 are shown in FIG. 10, whereas two further electronic components 124 in between are omitted in FIG. 10 for the sake of clarity). FIG. 11 shows another cross-sectional view of the package 100 according to FIG. 7. FIG. 12 shows a side view of the package 100 according to FIG. 7. FIG. 13 shows a plan view of the package 100 according to FIG. 7. The embodiment of FIGS. 7 - FIG. 13 can be realized as a gallium nitride power module, in particular having a molded single side cooled half bridge configuration. To a certain degree, FIGS. 7 - FIG. 13 are schematic, in particular FIGS. 9 and FIG. 10. Apart from only partially showing the electronic components 108, 124 in all said figures, gate pads 112 are omitted.

Also the package 100 according to FIGS. 7 - FIG. 13 comprises an inorganic carrier 102 of a ceramic material having a main surface 104 at which an electrically conductive pattern 106 in form of a patterned copper layer is formed. According to FIGS. 7 - FIG. 13, a plurality of electronic components 108, 124 is provided each having electrically conductive pads 110-112/130, 132 on one main surface thereof. This may be advantageous for providing a half bridge module. Each of the electronic components 108, 124 is mounted in a flip-chip configuration on the carrier 102 so that the pads 110-112/130, 132 of each electronic component 108, 124 are electrically coupled with the pattern 106. Moreover, an electrically conductive lateral thickening structure 114, which may be embodied as a leadframe structure, is arranged laterally from the electronic components 108, 124 and is electrically coupled with the respective pads 110-112/130, 132. Moreover, the configuration of the electrically insulating structure 122, the bond wire 136, the conductive bulk structure 118, the metal layer 130 and the encapsulant 120 may be as described above.

However, according to FIGS. 7 - FIG. 13, further electronic components 124 are provided in addition to electronic component 108. Referring to FIG. 7, an array 174 of high-side chips (four in the shown embodiment) as well as an array 176 of low-side chips (four in the shown embodiment) are illustrated, which may be interconnected to form a plurality of half bridges (four in the shown embodiment). Thus, eight electronic components 108, 124 are provided in the embodiment of FIGS. 7 - FIG. 13. Any other number of electronic components 108, 124 is possible. As shown in FIGS. 9 and FIG. 10, each of further electronic component 124 may have further electrically conductive pads 132, 134 (although two are shown, any number of pads is possible, for instance three in an embodiment in which the further electronic component 124 is a lateral transistor chip with a source pad, a drain pad and a gate pad). All electronic components 108, 124 are mounted in a flip-chip configuration on the carrier 102 so that also the further pads 132, 134 are electrically coupled with the pattern 106. For example, a different electrically conductive lateral thickening structure 114 may be respectively electrically coupled also with the further pads 132, 134. For instance, the electronic component 108 and the further electronic components 124 may be interconnected to form half bridges, although other electronic applications are possible.

In this embodiment, package 100 comprises a metal plate 144 arranged above the electronic components 108, 124 and covering or extending over the electronic components 108, 124. Metal plate 144 may be a curved metal plate. Metal plate 144 may be, for example, a copper sheet. Said metal plate 144 is electrically connected with the pattern 106 by metallic plate connectors 146 laterally enclosing the electronic components 108, 124. Together, the metal plate 144 and the metallic plate connectors 146 may form a U-shaped metallic structure in the cross-sectional view of FIG. 9. The metal plate 144 and the metallic plate connectors 146 connected to pattern 106 may form a direct current (DC) connection and may thus be denoted as DC+ plate and DC+ plate connectors, respectively. Referring to FIG. 9, metallic plate connectors 146 may be considered as further lateral thickening structure, in addition to lateral thickening structure 114. For example, a thickening structure does not necessarily have to be only a single piece of metal in a package. For instance, a thickening structure can comprise multiple separated pieces for connecting to different parts of a pattern 106 for achieving different electrical connections. Furthermore, lateral thickening structure 114 is shown in FIG. 7 with its different sections 114A, 114B, 114C, and 114D. In accordance with their electric interconnection and function during operation, section 114A of lateral thickening structure 114 may be denoted as alternating current (AC) section, sections 114B, 114D of lateral thickening structure 114 may be denoted as first direct current (DC+) section, and section 114C of lateral thickening structure 114 may be denoted as second direct current (DC-) section. The metal plate 144 may connect DC+ to the high side chips.

Reference sign 170 in FIG. 13 shows accessible package pins, like logical pins. For instance, said pins 170 may provide access to the gate connections of the transistor-type electronic components 108, 124, may provide access to a temperature sensor (such as a Kelvin emitter or a Kelvin source), and/or may provide access to one or more additional control connections to control the package 100.

The metallic plate connectors 146 are provided in addition to the (for example DCB-type) inorganic carrier 102. The metal plate connectors 146 connect only the array 174 of high-side chips with metal plate 144, not the array 176 of low-side chips.

FIG. 7 shows in a detail 199 sections 114A, 114C of the lateral thickening structure 114.

For example, any of sections 114A, 114C can be a Direct Copper Bonding substrate or a Direct Copper Bonding substrate plus an additional copper block. A part thereof can also be a thin copper layer and another part can be a thick copper layer. It is also possible to provide a thick copper layer which can be an additional copper block attached to a thin layer.

In the array 174 of dies, the left die pad may be a drain pad and may contact a metallic plate connector 146 and may finally connect to metal plate 144. The right die pad may be a source pad and may contact the section 114A and further finally connect to the AC connection, which may be the output of a half-bridge module or package. For the array 176 of dies, the die pads arrangement may be reversed: The right pad may be the drain pad (of the low side of a half bridge) and the left pad may be the source pad and may further connect to section 114C. All gate pads are omitted for simplicity.

FIG. 14 shows a cross-sectional view of a package 100 according to another exemplary embodiment. FIG. 15 shows a three-dimensional view of a bottom side of the package 100 according to FIG. 14. FIG. 16 shows a three-dimensional view of a top side of the package 100 according to FIG. 14.

The embodiment of FIGS. 14 - FIG. 16 differs from the embodiment of FIG. 1 in particular in that, according to FIGS. 14 - FIG. 16, conductive bulk structure 118 is omitted. Furthermore, leads provided by the lateral thickening structure 114 in the leaded package 100 according to FIGS. 14 - FIG. 16 are gull wing-shaped according to FIGS. 14- FIG. 16. Metal layer 130 on the ceramic plate of inorganic carrier 102 is exposed according to FIGS. 14 - FIG. 16 and therefore allows top side cooling and solderability on an optional heat sink (not shown).

The embodiment of FIGS. 14 - FIG. 16 shows an isolated discrete package which may be embodied for instance with TOLT design.

FIG. 17 shows a cross-sectional view of a package 100 according to another exemplary embodiment. FIG. 18 shows a three-dimensional view of the package 100 according to FIG. 17. FIG. 19 shows a cross-sectional view of the package 100 according to FIG. 17. Such an embodiment may be advantageous for chip embedding applications.

The embodiment of FIGS. 17 - FIG. 19 differs from the embodiment of FIG. 1 in particular in that, according to FIGS. 17 - FIG. 19, the lateral thickening structure 114 does not extend laterally out of the package 100. The package 100 according to FIGS. 17 - FIG. 19 comprises a laminate carrier 126 (which may be composed of laminated dielectric organic sheets, such as prepreg layers, and metal layers, for instance copper foils and copper vias) in which the inorganic carrier 102 with the pattern 106 and the metal layer 130, the electronic component 108 with the pads 110-112, the lateral thickening structure 114 and the encapsulant 120 (encapsulating, in an interior of the laminate carrier 126, in particular the inorganic carrier 102 with the pattern 106, the electronic component 108 with the pads 110-112 and the lateral thickening structure 114) are embedded.

According to FIGS. 17 - FIG. 19 and in particular referring to a detail 178 thereof, the lateral thickening structure 114 protrudes vertically beyond pattern 106 with a step 176 in between. Although the lateral thickening structure 114 according to FIGS. 17 - FIG. 19 does not extend over the sidewall of electronic component 108, lateral thickening structure 114 is electrically coupled with electrically conductive lateral vertical through connections 138. Said electrically conductive lateral vertical through connections 138 being connected or integrally formed with lateral thickening structure 114 extend vertically over the entire sidewalls of the electronic component 108. Moreover, a plurality of electrically conductive lateral vertical through connections 138 may be foreseen, for example four in the embodiment of FIGS. 17 - FIG. 19 . Between different ones or different groups of the electrically conductive lateral vertical through connections 138, the electronic component 108 is arranged. The electrically conductive lateral vertical through connections 138 may be embodied as metal vias, in particular copper vias. They may however also be metal pillars, such as copper pillars. The electrically conductive lateral vertical through connections 138 also extend through part of the encapsulant 120 and through part of the laminate carrier 126. In the shown embodiment, the electrically conductive lateral vertical through connections 138 extend up to an uppermost metal layer 180 forming part of a top main surface of package 100. The electronic component 108 embedded in encapsulant 120 being embedded, in turn, in the laminate carrier 126, is thus electrically coupled with an electronic periphery via pads 110-112, pattern 106, lateral thickening structure 114 and electrically conductive lateral vertical through connections 138 extending up to exposed metal layer 180.

Moreover, the package 100 according to FIGS. 17 - FIG. 19 comprises an array of thermally conductive vertical through connections 140 arranged laterally side-by-side and extending from a bottom side of the inorganic carrier 102 through the laminate carrier 126 up to a bottom main surface of the package 100. More specifically, the thermally conductive vertical through connections 140 extend up to an exterior metal layer 142 at the bottom main surface of the package 100. The portion of package 100 below electronic component 108 may constitute a thermal dissipation path.

FIG. 20 shows a cross-sectional view of a package 100 according to another exemplary embodiment. FIG. 21 shows a three-dimensional view of a top side of the package 100 according to FIG. 20. FIG. 22 shows a three-dimensional view of a bottom side of the package 100 according to FIG. 20.

The embodiment of FIGS. 20 - FIG. 22 differs from the embodiment of FIGS. 14 - FIG. 16 in particular in that, according to FIGS. 20 - FIG. 22 , no gull wing-shaped leads are provided. Thus, the package 100 according to FIGS. 20 - FIG. 22 is a leadless package. More specifically, the package 100 of the presently described embodiment is an isolated discrete package with bottom sided cooling and a leadless configuration.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
an inorganic carrier having a main surface at which an electrically conductive pattern is formed;
an electronic component having electrically conductive pads and being mounted in a flip-chip configuration on the carrier so that the pads are electrically coupled with the electrically conductive pattern;
an electrically conductive lateral thickening structure arranged laterally from the electronic component and being electrically coupled with at least part of the pads; and
an encapsulant encapsulating at least part of the electronic component and part of the lateral thickening structure, wherein a portion of the lateral thickening structure being exposed with respect to the encapsulant has a thickness being larger than a thickness of the electrically conductive pattern and forms at least one lead.

2. The package of claim 1, wherein the electrically conductive pattern has a thickness in a range from 10 µm to 30 µm.

3. The package of claim 1, wherein the lateral thickening structure has a thickness in a range from 200 µm to 500 µm.

4. The package of claim 1, wherein the electronic component is a lateral power chip.

5. The package of claim 1, wherein a lateral dimension of a gap between adjacent ones of the pads is substantially the same as a lateral dimension of a gap between two adjacent elements of the electrically conductive pattern.

6. The package of claim 1, wherein each of the pads is substantially fully overlapping with a corresponding one of elements of the electrically conductive pattern.

7. The package of claim 1, wherein the lateral thickening structure comprises at least one of a leadframe structure, a galvanic plating structure, or a metallic paste structure.

8. The package of claim 1, wherein the inorganic carrier has, opposing the main surface, a further main surface on or over which a conductive bulk structure is formed which has a thickness larger than a thickness of the electrically conductive pattern.

9. The package of claim 8, wherein the inorganic carrier has a heat dissipating metal layer directly on the further main surface and connected with the conductive bulk structure.

10. The package of claim 9, wherein at least one of:
the conductive bulk structure has a thickness in a range from 200 µm to 500 µm;
the conductive bulk structure comprises a leadframe structure; and
a thickness of the heat dissipating metal layer is substantially the same as a thickness of the electrically conductive pattern.

11. The package of claim 8, wherein a portion of the conductive bulk structure is exposed with respect to the encapsulant.

12. The package of claim 1, further comprising an electrically insulating structure between adjacent ones of the pads and between corresponding adjacent sections of the electrically conductive pattern.

13. The package of claim 12, wherein:
a material of the encapsulant is different from a material of the electrically insulating structure; or
a portion of the encapsulant forms the electrically insulating structure.

14. The package of claim 1, further comprising at least one further electronic component having further electrically conductive pads and being mounted in a flip-chip configuration on the carrier so that the further pads are electrically coupled with the electrically conductive pattern, wherein the electrically conductive lateral thickening structure is electrically coupled with at least part of the further pads.

15. The package of claim 14, wherein at least one of:
the electronic component and the at least one further electronic component are interconnected to form at least one half bridge;
a metal plate extends over both the electronic component and the at least one further electronic component; and
a metal plate above at least one of the electronic component and the at least one further electronic component is connected with the electrically conductive pattern by metallic plate connectors laterally enclosing the electronic component and the at least one further electronic component.

16. The package of claim 1, further comprising a laminate carrier in which the inorganic carrier with the electrically conductive pattern, the electronic component with the pads and the lateral thickening structure are embedded.

17. The package of claim 16, wherein at least one of:
an encapsulant encapsulates, in an interior of the laminate carrier, at least part of the inorganic carrier with the electrically conductive pattern, the electronic component with the pads and the lateral thickening structure;
the lateral thickening structure is electrically coupled with electrically conductive lateral vertical through connections between which the electronic component is arranged and which extend through the laminate carrier; and
thermally conductive vertical through connections extend from a bottom side of the inorganic carrier through the laminate carrier up to a bottom main surface of the package, in particular up to an exterior metal layer at the bottom main surface of the package.

18. The package of claim 1, wherein at least one of:
a lateral spacing between adjacent sections of the electrically conductive pattern is in a range from 5 µm to 20 µm;
the package is configured as a leaded package or a leadless package;
the inorganic carrier comprises a ceramic material and/or a diamond material;
the lateral thickening structure is thermally conductive; and
a bond wire has a first end connected to a back side of the electronic component and a second end connected to the thickening structure.

19. A method of manufacturing a package, the method comprising:
providing an inorganic carrier having a main surface at which an electrically conductive pattern is formed;
mounting an electronic component in a flip-chip configuration on the carrier so that electrically conductive pads of the electronic component are electrically coupled with the electrically conductive pattern; and
arranging an electrically conductive lateral thickening structure laterally from the electronic component and being electrically coupled with at least part of the pads; and
encapsulating at least part of the electronic component and part of the lateral thickening structure by an encapsulant, wherein a portion of the lateral thickening structure being exposed with respect to the encapsulant has a thickness being larger than a thickness of the electrically conductive pattern and forms at least one lead.
